(19) United States
(12) Patent Application Publication
(10) Pub. No.: US 2016/0267946 A1
(43) Pub. Date: Sep. 15, 2016

(54) STACK MEMORY DEVICE AND METHOD FOR OPERATING SAME

(71) Applicant: SILICONFILE TECHNOLOGIES INC., Gyeonggi-do (KR)

(72) Inventors: Sang Wook Ahn, Gyeonggi-do (KR); Huy Chan Jung, Gyeonggi-do (KR); Yong Woon Lee, Gyeonggi-do (KR); Heui-Gyun Ahn, Gyeonggi-do (KR); Do Young Lee, Gyeonggi-do (KR)

(21) Appl. No.: 15/032,935

(22) PCT Filed: Oct. 27, 2014
(86) PCT No.: PCT/KR2014/010123

§ 371 Date: Apr. 28, 2016

(30) Foreign Application Priority Data
Oct. 28, 2013 (KR) 10-2013-0128204

(51) Int. Cl. G11C 5/02; G11C 8/06; G11C 8/10; H01L 25/065; G11C 5/06; H01L 23/48

(52) U.S. Cl. CPC G11C 5/025; G11C 5/063; H01L 23/481; G11C 8/10; H01L 25/0657; G11C 8/06; H01L 2225/06541

(57) ABSTRACT

The present invention provides a stack memory device and a method for operating same. The stack memory device, according to the present invention, is provided with: a first memory chip in which first type memory cells are repeatedly arranged in row direction and column direction, and which comprises one or more cell arrays, in which a dump line is connected to the each first type memory cell; and a second memory chip in which second type memory cells are repeatedly arranged in row direction and column direction, and which comprises one or more cell arrays, in which a dump line is connected to the each second type memory cell, wherein first pads are connected to the dump lines of the first type memory cells and second pads are connected to the dump lines of the second type memory cells, the first pads and the second pads having one-to-one correspondence.

### TECHNICAL FIELD

The present invention relates to a stack memory device for storing data, and more specifically, to a stack memory device and a method for operating the same that data is dumped between a plurality of stacked memory chips.

### BACKGROUND ART

As semiconductor memory device may store a lot of data. Such a semiconductor memory device is mainly used in an equipment, e.g., a computer or a mobile phone, which needs to store lots of data. Recently, as the computer or the mobile phone has been spread widely, the needs to increase a data storage capacity or a data processing speed has been requested. Thus a manufacturer of the semiconductor memory device has been developed to increase a memory capacitor, and the memory capacity is greatly increased by reducing the size of the memory elements of a memory circuit.

However, as the memory elements are restricted in the size reduction, to increase the memory capacity of the memory chip reaches the limitations in a current technology. Thus, a semiconductor memory package having a plurality of stacked memory chips has been developed. Such a package technology has an effect in the increase of the memory capacity of the memory chip, but has not a remarkable effect in the data processing speed. Moreover, it is more important for a memory device, e.g., a cache memory, which needs a fast processing speed. Thus, the development of a memory device having an increased data capacity and an improved data processing speed has been requested continuously.

### DISCLOSURE

### Technical Problem

The present invention is directed to a stack memory device and a method for operating same for improving a processing speed of a memory data.

### Technical Solution

In accordance with an embodiment of the present invention, a stack memory device may include a first memory chip including at least one cell array having a plurality of first type memory cells, wherein the plurality of first type memory cells are repeatedly arrayed along a row direction and a column direction and a dump line is coupled to each of the plurality of first type memory cells; and a second memory chip including at least one cell array having a plurality of second type memory cells, wherein the plurality of second type memory cells are repeatedly arrayed along the row direction and the column direction and a dump line is coupled to each of the plurality of second type memory cells, wherein a first pad is coupled to the dump line coupled to the plurality of first type memory cells, a second pad is coupled to the dump line coupled to the plurality of second type memory cells, and the first pad corresponds to the second pad by one to one.

In accordance with an embodiment of the present invention, a method for operating a stack memory device may include steps of driving a plurality of first type memory cells, which are repeatedly arrayed along a row direction and a column direction and included in a first memory chip, in the row direction; loading binary information, which are stored in the plurality of first type memory cells by the driving of the first type memory cells, to a dump line coupled to each of the plurality of first type memory cells; and transferring loaded binary information to a plurality of second type memory cells, which are repeatedly arrayed along the row direction and the column direction and included in a second memory chip.

In accordance with an embodiment of the present invention, a stack memory device may include a first memory chip including a plurality of first type memory cells, a plurality of first pads and a plurality of first dump lines, wherein the plurality of first type memory cells are repeatedly arrayed along a row direction and a column direction, and the plurality of first dump lines couple the plurality of first type memory cells to the plurality of first pads by one to one; and a second memory chip including a plurality of second type memory cells, a plurality of second dump lines, a plurality of second pads and a plurality of dump selection switches, wherein the plurality of second type memory cells are arrayed along the row direction and the column direction, each of the plurality of second dump lines are coupled to each of the plurality of second type memory cells, the plurality of second pads are coupled to the plurality of second dump lines, and each of the plurality of dump selection switches is coupled to a specific location of each of the plurality of second dump lines, wherein a plurality of first pads are coupled to the plurality of second pads by one to one, and the plurality of second pads are coupled to the plurality of second dump lines by one to multiple.

In accordance with an embodiment of the present invention, a method for operating a stack memory device may include the steps of driving a plurality of first type memory cells, which are arrayed along a row direction and a column direction, in the row direction; loading binary information, which are stored in the plurality of first type memory cells by the driving of the plurality of first type memory cells, to a plurality of first dump lines; dumping the binary information, which are loaded on the plurality of first dump lines, to each of a plurality of second dump lines coupled to the plurality of first dump lines; and transferring the binary information which are dumped to the plurality of second dump lines, to a plurality of second type memory cells coupled to each of the plurality of second dump lines.

### Advantageous Effects

As described above, according to the present invention, the data stored in the plurality of memory chips are transferred directly to each other without a peripheral circuit or lines which are coupled to an external device by correspondingly coupling a plurality of memory cells included in a first memory chip to a plurality of memory cells included in a second memory chip.

Thus, a data transfer speed between the plurality of memory chips is greatly increased, and a data storage capacity of the stack memory device is greatly increased.

### DESCRIPTION OF DRAWINGS

FIG. 1 is a block diagram illustrating a stack memory device in accordance with the present invention.

FIG. 2 is a circuit diagram of a stack memory device where a first type memory cell and a second type memory cell are corresponding to each other by one to one in accordance with the present invention.

FIG. 3 is a circuit diagram of a stack memory device where a first type memory cell and second type memory cells are corresponding to each other by one to multiple in accordance with the present invention.

### BEST MODE

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like parts in the various figures and embodiments of the present invention. In this specification, specific terms have been used. The terms are used to describe the present invention, and are not used to qualify the sense or limit the scope of the present invention.

It is also noted that in this specification ‘and/or’ represents that one or more of components arranged before and after ‘and/or’ is included. Furthermore, “connected/coupled” refers to one component not only directly coupling another component but also indirectly coupling another component through an intermediate component In addition, a singular form may include a plural form as long as it is not specifically mentioned in a sentence. Furthermore, ‘include/comprise’ or ‘including/comprising’ used in the specification represents that one or more components, steps, operations, and elements exists or are added.

Hereinafter, various embodiments will be described below in more detail with reference to the accompanying drawings such that a skilled person in this art understand and implement the present invention easily.

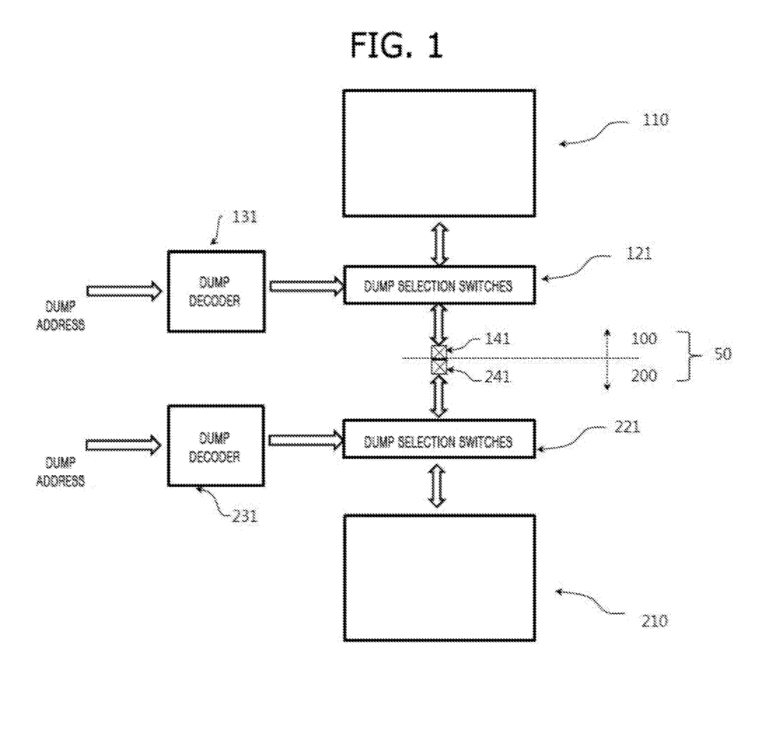

FIG. 1 is a block diagram illustrating a stack memory device in accordance with the present invention. Referring to FIG. 1, a stack memory device 50 includes a first memory chip 100, which is stacked on a second memory chip.

The first memory chip 100 includes a first memory cell array 110, a plurality of dump selection switches 121, a first dump decoder 131 and a plurality of first pads 141.

The first memory cell array 110 includes a plurality of first type memory cells. The plurality of first type memory cells may store a binary data. The plurality of first type memory cells may be classified into a plurality of memory cell groups. The plurality of first type memory cells are arrayed along a column direction and a row direction in the first memory cell array 110. As not shown in FIG. 1, the first memory cell array 110 includes a plurality of bit lines and a plurality of word lines. The plurality of bit lines and the plurality of word lines are coupled to the plurality of first type memory cells. The plurality of bit lines and the plurality of word lines are not used for data dump between the first memory chip 100 and the second memory chip 200, but used for receiving data from the outside of the first memory chip 100 or transferring data to the outside of the first memory chip 100. Also, as not shown in FIG. 1, the first memory chip 100 further include a column decoder for indicating one of the plurality of bit lines and a row decoder for indicating one of the plurality of word lines.

Since the plurality of bit lines, the plurality of word lines, the column decoder and the row decoder included in the first memory chip 100 may be configured using a conventional technique, their detailed descriptions will be omitted.

Each of the plurality of first type memory cells may be a volatile memory cell such as a dynamic random access memory (DRAM) cell and a static random access memory (SRAM) cell, or a non-volatile memory cell such as a flash memory cell.

A plurality of first dump selection switches 121 are coupled between the first memory cell array 110 and a plurality of first pads 141. The plurality of first dump selection switches 121 transfer data outputted from the first memory cell array 110 to the plurality of first pads 141, or transfer data outputted from the plurality of first pads 141 to the first memory cell array 110. That is, if the plurality of first dump selection switches 121 are activated, the data outputted from the first memory cell array 110 is transferred to the plurality of first pads 141, or the data outputted from the plurality of first pads 141 is transferred to the first memory cell array 110, and otherwise, the plurality of first dump selection switches 121 does not transfer the data. Each of the plurality of first dump selection switches 121 may include a PMOS transistor or an NMOS transistor. The plurality of first dump selection switches 121 are coupled to the plurality of first type memory cells included in the first memory cell array 110 by one to one.

The plurality of first dump selection switches 121 may be classified into a plurality of dump selection switch groups. Herein, each of the plurality of dump selection switch groups is coupled to one of the plurality of memory cell groups. That is, the plurality of dump selection switch groups are coupled to the plurality of memory cell groups by one to one.

Like this, the number of the plurality of dump selection switch groups is same as the number of the plurality of memory cell groups. For example, if the number of the plurality of dump selection switch groups is two, the number of the plurality of memory cell groups is two, and if the number of the plurality of dump selection switch groups is four, the number of the plurality of memory cell groups is four.

Also, when the data is dumped from the first memory chip 100 to the second memory chip 200, the plurality of memory cell groups simultaneously outputs data stored in the plurality memory cells included in the plurality of memory cell groups, respectively, and thus, the plurality of dump selection switch groups simultaneously transfer received data to the plurality of first pads 141.

The first dump decoder 131 is coupled to the plurality of first dump selection switches 121. The first dump decoder 131 indicates an address of the plurality of first dup selection switches 121. That is, on or off of the plurality of first dump selection switches 121 is determined by the first dump decoder 131. The first dump decoder 131 switches on simultaneously the plurality of first dump selection switches 121 or switches on the grouped first dump selection switches. Also, the first dump decoder 131 may be set to separately switch on the plurality of first dump switches 121. The first dump decoder 131 receives an address for indicating the plurality of first dump selection switches 121 from the outside of the first memory chip 100.

The plurality of first pads 141 are coupled to the plurality of first dump selection switches 121 and a plurality of second pads 241 included in the second memory chip 200. Each of the plurality of first pads 141 is coupled to one of the plurality of first dump selection switches 121. That is, the plurality of first pads 141 are coupled to the plurality of first dump selection switches 121 by one to one.

In case that the plurality of first dump selection switches 121 are classified into the plurality of dump selection switch groups, the plurality of first pads 141 are commonly coupled to the plurality of dump selection switch groups. Herein, the plurality of first pads 141 are coupled to some (same as the number of the plurality of dump selection switch groups) of the plurality of first dump selection switches 121. For example, in case that the plurality first dump selection switches 121 are classified into a first dump selection switch group and a second dump selection switch, the plurality of first pads 141 is commonly coupled to one of the switches included in the first dump selection switch group and one of the switches included in the second dump selection switch group.

The plurality of first pads 141 and the plurality of second pads 241 may be bonded to each other using a through-silicon-via (TSV) technology or a direct bonding interconnect (DBI) technology.

The second memory chip 200 includes a second memory ell array 210, a plurality of second dump selection switches 221, a second dump decoder 231 and the plurality of second pads 241.

The second memory cell array 210 includes a plurality of second type memory cells. The plurality of second type memory cells may store a binary data. The plurality of second type memory cells may be classified into a plurality of memory cell groups. The plurality of second type memory cells are arrayed along a column direction and a row direction in the second memory cell array 210. As not shown in FIG. 1, the second memory cell array 210 includes a plurality of bit lines and a plurality of word lines. The plurality of bit lines and the plurality of word lines are coupled to the plurality of second type memory cells. The plurality of bit lines and the plurality of word lines are not used for data dump between the first memory chip 100 and the second memory chip 200, but used for receiving data from the outside of the second memory chip 200 or transferring data to the outside of the second memory chip 200. Also, as not shown in FIG. 1, the second memory chip 200 further include a column decoder for indicating one of the plurality of bit lines and a row decoder for indicating one of the plurality of word lines.

Since the plurality of bit lines, the plurality of word lines, the column decoder and the row decoder included in the second memory chip 200 may be configured using a conventional technique, their detailed descriptions will be omitted.

Each of the plurality of second type memory cells may be a volatile memory cell such as a DRAM cell and an SRAM cell, or a non-volatile memory cell such as a flash memory cell.

A plurality of second dump selection switches 221 are coupled between the second memory cell array 210 and a plurality of second pads 141. The plurality of second dump selection switches 221 transfer data outputted from the second memory cell array 210 to the plurality of second pads 241 or transfer data outputted from the plurality of second pads 241 to the second memory cell array 210. That is, if the plurality of second dump selection switches 221 are activated, the data outputted from the second memory cell array 210 is transferred to the plurality of second pads 241, or the data outputted from the plurality of second pads 241 is transferred to the second memory cell array 210, and otherwise, the plurality of second dump selection switches 221 does not transfer the data.

Each of the plurality of second dump selection switches 221 may include a PMOS transistor or an NMOS transistor. The plurality of second dump selection switches 221 are coupled to the plurality of second type memory cells included in the second memory cell array 210 by one to one.

The plurality of second dump selection switches 221 may be classified into a plurality of dump selection switch groups. Herein, each of the plurality of dump selection switch groups is coupled to one of the plurality of memory cell groups. That is, the plurality of dump selection switch groups are coupled to the plurality of memory cell groups by one to one.

Like this, the number of the plurality of dump selection switch groups is same as the number of the plurality of memory cell groups. For example, if the number of the plurality of dump selection switch groups is two, the number of the plurality of memory cell groups is two, and if the number of the plurality of dump selection switch groups is four the number of the plurality of memory cell groups is four.

Also, when the data is dumped from the first memory chip 100 to the second memory chip 200, the plurality of dump selection switch groups simultaneously writes data, which are simultaneously received from the plurality of second pads 241, in the plurality of memory cells included in each of the plurality of memory cell groups.

The second dump decoder 231 is coupled to the plurality of second dump selection switches 221. The second dump decoder 231 indicates an address of the plurality of second dump selection switches 221. That is, on or off of the plurality of second dump selection switches 221 is determined by the second dump decoder 231. The second dump decoder 231 switches on simultaneously the plurality of second dump selection switches 221 or switches on the grouped second dump selection switches. Also, the second dump decoder 231 may be set to separately switch on the plurality of second dump switches 221. The second dump decoder 231 receives an address for indicating the plurality of second dump selection switches 221 from the outside of the second memory chip 200.

The plurality of second pads 241 are coupled to the plurality of second dump selection switches 221 and a plurality of first pads 141 included in the first memory chip 100. Each of the plurality of second pads 241 is coupled to one of the plurality of second dump selection switches 221. That is, the plurality of second pads 241 are coupled to the plurality of second dump selection switches 221 by one to one.

In case that the plurality of second dump selection switches 221 are classified into the plurality of dump selection switch groups, the plurality of second pads 241 are commonly coupled to the plurality of dump selection switch groups. Herein, the plurality of second pads 241 are coupled to some (same as the number of the plurality of dump selection switch groups) of the plurality of second dump selection switches 221. For example, in case that the plurality second dump selection switches 221 are classified into a third dump selection switch group and fourth dump selection switch, the plurality of second pads 241 is commonly coupled to one of the switches included in the third dump selection switch group and one of the switches included in the fourth dump selection switch group.

As described above, according to the present invention, the data stored in the plurality of first type memory cells of the first memory chip 100 may be directly dumped to the plurality of second type memory cells of the second memory chip 200. That is, the data stored in the first memory chip 100 may be directly transferred to the second memory chip 200 without lines and a peripheral circuit which are coupled to the outside.

Thus, the data transfer speed between the first memo chip 100 and the second memory chip 200 is greatly increased, and a data capacity of the stack memory device 50 is greatly increased.

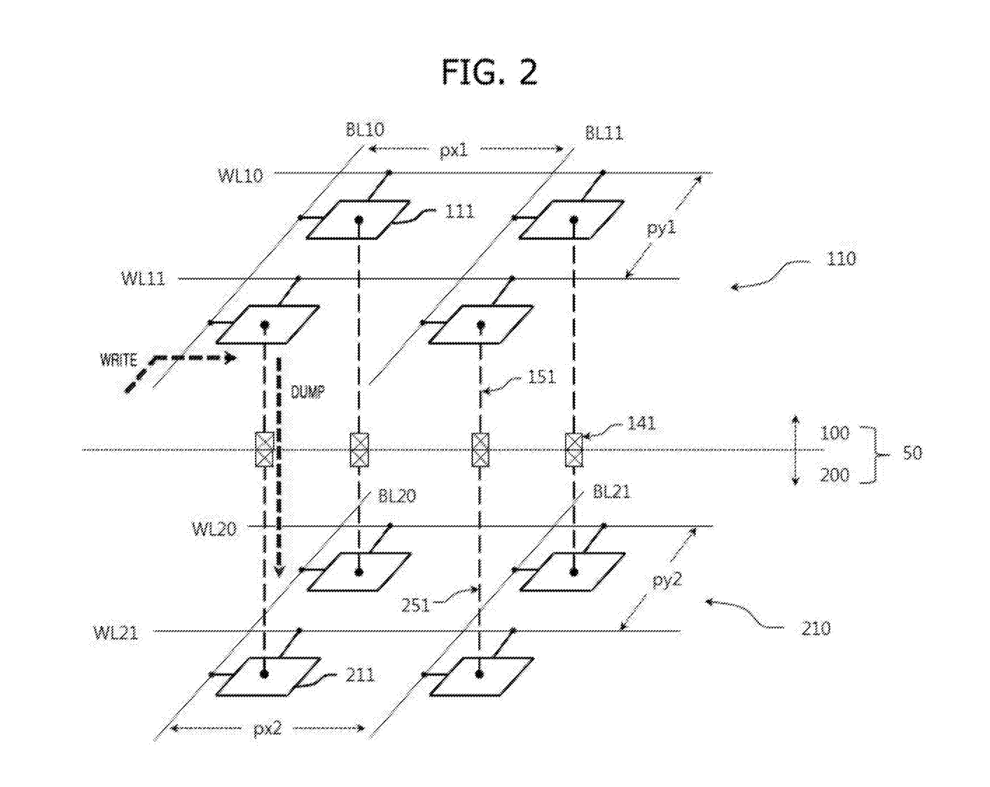

FIG. 2 is a circuit diagram of a stack memory device 50 where a first type memory cell and a second type memory cell are corresponding to each other by one to one in accordance with the present invention. Referring to FIG. 2, the stack memory device 50 includes the first memory chip 100 which is stacked on the second memory chip 200.

The first memory chip 100 includes at least one memory cell array 110 where first type memory cells 111 are repeatedly arrayed along a column direction and a row direction and dump lines 151 are coupled to the first type memory cells 111, respectively.

More specifically, the first memory chip 100 includes the first memory cell array 110, the plurality of dump lines 151 and a plurality of first pads 141.

The first memory cell array 110 includes the first type memory cells 111 which are repeated arrayed along the column direction and the row direction. The plurality of first type memory cells 111 are coupled to the plurality of first dump lines 151. That is, the plurality of first type memory cells 111 are coupled to the plurality of first dump lines 151 by one to one.

The plurality of first type memory ells may store a binary data, respectively. A plurality of bit lines BL10 and BL11 and a plurality of word lines WL10 and WL11 are coupled to the plurality of memory cells 111. The plurality of bit lines BL10 and BL11 and the plurality of word lines WL10 and WL11 are not used for the data dump between the first memory chip 100 and the second memory chip 200, but used for receiving data from the outside of the first memory chip 100 or transferring the data to the outside of the first memory chip 100. Also, as not shown in FIG. 2 the first memory chip 100 further includes a column decoder for indicating the plurality of bit lines BL10 and BL11 and a row decoder for indicating the plurality of word lines WL10 and WL11.

Each of the plurality of first type memory cells 111 may be a volatile memory cell such as a DRAM cell and an SRAM cell, or a non-volatile memory cell such as a flash memory cell.

The plurality of first dump lines 151 are coupled to the plurality of first pads 141. That is, the plurality of first dump lines 151 are coupled to the plurality of first pads 141 by one to one.

As not shown in FIG. 2, a plurality of dump selection switches may be further coupled to the plurality of first dump lines 151. Herein, the plurality of first dump selection switches are coupled to the plurality of first dump lines 151 which couples one of the plurality of memory cells to one of the plurality of first pads 141. In case of the plurality of first dump selection switches are included in the first memory chip 100, a first dump decoder may be further included in the first memory chip 100. The first dump decoder indicates an address of the plurality of first dump selection switches. That is, the plurality of first dump selection switches are switched on or off by the first dump decoder. Thus, the data outputted from the plurality of first type memory cells 111 is transferred or not to the plurality of first pads 141.

The second memory chip 200 includes at least one second memory cell array 210 where second type memory cells 211 are repeatedly arrayed along a column direction and a row direction and dump lines 251 are coupled to the second type memory cells 211, respectively.

More specifically, the second memory chip 200 includes the second memory cell array 210, the plurality of dump lines 251 and a plurality of second pads 241.

The second memory cell array 210 includes the second type memory cells 211 which are repeated arrayed along the column direction and the row direction. The plurality of second type memory cells may store a binary data, respectively. A plurality of bit lines BL20 and BL21 and a plurality of word lines WL20 and WL21 are coupled to the plurality of second type memory cells 211. The plurality of bit lines BL20 and BL21 and the plurality of word lines WL20 and WL21 are not used for the data dump between the first memory chip 100 and the second memory chip 200, but used for receiving data from the outside of the second memory chip 200 or transferring the data to the outside of the second memory chip 200. Also, as not shown in FIG. 2, the second memory chip 200 further includes a column decoder for indicating the plurality of bit lines BL20 and BL21 and a row decoder for indicating the plurality of word lines WL20 and WL21.

The plurality of second type memory cells 211 are coupled to the plurality of second dump lines 251. That is, the plurality of second type memory cells 211 are coupled to the plurality of second dump lines 251 by one to one.

Each of the plurality of second type memory cells 211 may be a volatile memory cell such as a DRAM cell and an SRAM cell, or a non-volatile memory cell such as a flash memory cell.

The plurality of second dump lines 251 are coupled to the plurality of second pads 241. That is, the plurality of second dump lines 251 are coupled to the plurality of second pads 241 by one to one.

As not shown in FIG. 2, a plurality of dump selection switches may be further coupled to the plurality of second dump lines 251. That is, the plurality of second dump selection switches are coupled between one of the plurality of memory cells and one of the plurality of second pads 241. In case of the plurality of second dump selection switches are included in the second memory chip 200, the second memory chip 200 may further include a second dump decoder. The second dump decoder indicates an address of the plurality of second dump selection switches. That is, the plurality of second dump selection switches are switched on or off by the second dump decoder. Thus, the data outputted from the plurality of second type memory cells 211 is transferred or not to the plurality of second pads 241.

A pitch px1 of a row direction of the plurality of first type memory cells 111 is same as a pitch px2 of a row direction of the plurality of second type memory cells 211, or a pitch py1 of a column direction of the plurality of first type memory cells 111 is same as a pitch py2 of a column direction of the plurality of second type memory cells 211.

A method for operating the stack memory device 50 will be described as follows.

The method for operating the stack memory device 50 includes a step of driving the plurality of first type memory cells 111, which are repeatedly arrayed along a row direction and a column direction, in a row direction, a step of loading binary information, which is stored in the plurality of first type memory cells 111 by the driving step, on the plurality of dump lines 151 coupled to the plurality of first type memory cells 111, and a step of transferring the loaded binary information to the plurality of second type memory cells 211, which are repeatedly arrayed along the row direction and the column direction.

The transferring step is performed by a switching operation of at least one switch among the plurality of dump selection switches of the first memory chip 100 or the second memory chip 200. For example, when the dump selection switches included in the first memory chip 100 are switched on by the dump decoder included in the first memory chip 100, or the dump selection switches included in the second memory chip 200 are switched on by the dump decoder included in the second memory chip 200, the data is dumped from the first memory chip 100 to the second memory chip 200.

The switching operation is performed by an address that selectively switches some or ail of the plurality of dump selection switches coupled to the first memory cell array 110 or the second memory cell array 210 For example, when the plurality of dump selection switches included in the first memory chip 100 or the plurality of dump selection switches included in the second memory chip 200 are switched, or when all of the plurality of dump selection switches included in the first memory chip 100 and the second memory chip 200, the switching operation may be performed.

The transferring step may be performed through the plurality of first pads 141 coupled to the plurality of first type memory cells 111 and the plurality of second pads 241 coupled to the plurality of second type memory cells 211.

The data may be dumped from the second memory chip 200 to the first memory chip 100 by an operation similar to the operation described above.

As described above, according to the present invention, the data stored in the plurality of first type memory cells 111 of the first memory chip 100 may be directly dumped to the plurality of second type memory cells 211 of the second memory chip 200. That is, the data stored in the first memory chip 100 may be directly transferred to the second memory chip 200 without lines and peripheral circuits coupled to the outside.

Thus, the data transfer speed between the first memory chip 100 and the second memory chip 200 is greatly increased and the data capacity of the stack memory device 50 is greatly increased.

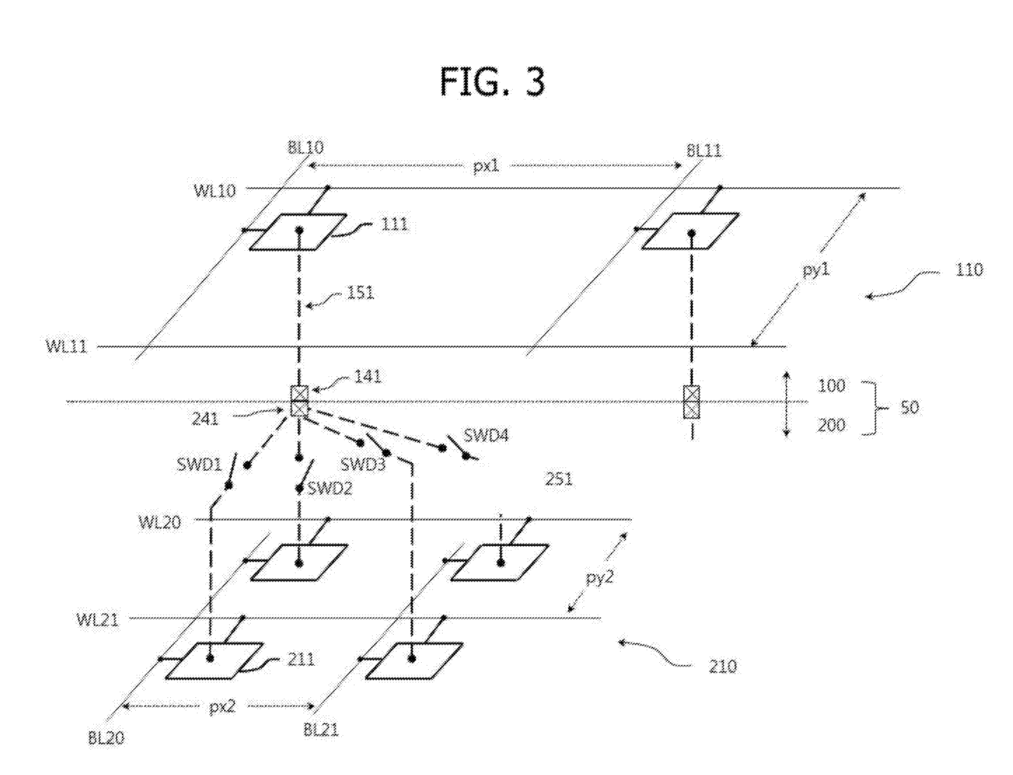

FIG. 3 is a circuit diagram of a stack memory device 50 where a first type memory cell 111 and second type memory cells 211 are corresponding to each other by one to multiple in accordance with the present invention. Referring to FIG. 3, the first memory chip 100 is stacked on the second memory chip 200.

The first memory chip 100 includes a plurality of first type memory cells 111, a plurality o first pads 141 and a plurality of first dump lines 151.

The plurality of first type memory cells 111 are repeatedly arrayed along a row direction and a column direction. Each of the plurality of first type memory cells 111 may store binary data. A plurality of bit lines BL10 and BL11 and a plurality of word lines WL10 and WL11 are coupled to the plurality of first type memory cells 111. The plurality of bit lines BL10 and BL11 and the plurality of word lines WL10 and WL11 are not used for the data dump between the first memory chip 100 and the second memory chip 200, but used for receiving data from the outside of the first memory chip 100 or transferring the data to the outside of the first memory chip 100. Also, as not shown in FIG. 3, the first memory chip 100 further includes a column decoder for indicating one of the plurality of bit lines BL10 and BL11 and a row decoder for indicating one of the plurality of word lines WL10 and WL11.

Each of the plurality of first type memory cells 111 may be a volatile memory cell such as a DRAM cell and an SRAM cell, or a non-volatile memory cell such as a flash memory cell.

The plurality of first dump lines 151 couples the plurality of first pads 141 to the plurality of first type memory cells 111 by one to one.

As not shown in FIG. 3, a plurality of dump selection switches may be further coupled to the plurality of first dump lines 151. In case of the plurality of first dump selection switches are included in the first memory chip, a first dump decoder may be further included. The first dump decoder indicates an address of the plurality of first dump selection switches. That is, the plurality of first dump selection switches are switched on or off by the first dump decoder. Thus, the data outputted from the plurality of first type memory cells 111 is transferred or not to the plurality of first pads 141.

The second memory chip 200 includes a plurality of second type memory cells 211, a plurality of second dump lines 251, a plurality of second pads 241 and a plurality of dump selection switches SWD1 to SWD4.

The plurality of second type memory cells 211 are repeatedly arrayed along a row direction and a column direction. The plurality of second type memory cells 211 may store binary data, respectively. A plurality of bit lines BL20 and BL21 and a plurality of word lines WL20 and WL21 are coupled to the plurality of second type memory cells 211. The plurality of bit lines BL20 and BL21 and the plurality of word lines WL20 and WL21 are not used for the data dump between the first memory chip 100 and the second memory chip 200, but used for receiving data from the outside of the second memory chip 200 or transferring the data to the outside of the second memory chip 200. Also, as not shown in FIG. 3, the second memory chip 200 further includes a column decoder for indicating one of the plurality of bit lines BL20 and BL21 and a row decoder for indicating one of the plurality of word lines WL20 and WL21.

Since the plurality of bit lines BL10, BL11, BL20 and BL21 and the plurality of word lines WL10, WL11, WL 20 and WL21, the column decoder and the row decoder included in each of the first memory chip 100 and the second memory chip 200 may be configured using a conventional technique, their detailed descriptions will be omitted.

Each of the plurality of second type memory cells 211 may be a volatile memory cell such as a DRAM cell and an SRAM cell, or a non-volatile memory cell such as a flash memory cell.

The plurality of second dump lines 251 are coupled to the plurality of second type memory cells 211 by one to one.

The plurality of second pads 241 are coupled to the plurality of second dump lines 251 and the plurality of first pads 141. Herein, the plurality of second pads 241 are coupled to the plurality of dump lines 251 by one to multiple. Also, the plurality of second pads 241 are coupled to the plurality of first pads 141. The plurality of first pads 141 and the plurality of second pads 241 may bonded to each other by the TSV technique or the DBI technique.

The plurality of dump selection switches SWD1 to SWD4 are coupled to a specific location of each of the plurality of second dump lines 251. That is, it is preferable that the plurality of dump selection switches SWD1 to SWD4 are coupled to a middle of each of the plurality of second dump lines 251, but the plurality of dump selection switches SWD1 to SWD4 may be coupled to an end of the plurality of second dump lines 251.

The second memory chip 200 may further include a dump decoder for indicating an address of the plurality of dump selection switches SWD1 to SWD4. It is determined that the plurality of dump selection switches SWD1 to SWD4 are switched on or off by the dump decoder. The dump decoder may switch on simultaneously or separately the plurality of dump selection switches SWD1 to SWD4. The dump decoder receives an address signal from the outside of the second memory chip 200. A plurality of dump decoders may be included in the second memory chip 200, the plurality of dump selection switches SWD1 to SWD4 may be classified into grouped dump selection switches, and the plurality of dump decoders may control the grouped dump selection switches.

As shown in FIG. 3, in case that four dump lines 251 of the second memory chip 200 are coupled to one dump line 151 of the first memory chip 100, the pitches px1 and py1 of the dump line 151 of the first memory chip 100 may be different from the pitches px2 and py2 of the dump line 251 of the second memory chip 200. In repeated memory cell array, in order to smoothly couple the first and second type memory cells 111 and 211 having different pitches, it is preferable that the pitches px1 and py1 of the first type memory cells 111 of the first memory chip 100 are integer multiples of the pitches px2 and py2 of the second type memory cells 211 of the second memory chip 200.

A method for operating the stack memory device 50 will be described.

The method for operating the stack memory device 50 includes a step of driving the plurality of first type memory cells 111 in a row direction, a step of loading binary information stored in the plurality of first type memory cells 111 by the driving step on the plurality of first dump lines 151, a step of dumping the binary information loaded on the plurality of first dump lines 151 to the plurality of second dump lines 251, and a step of transferring the binary information dumped to the plurality of second dump lines 251 to the plurality of second type memory cells 211.

The transferring step is performed by at least one switching operation among the plurality of dump selection switches SWD1 to SWD4 coupled to the plurality of second dump lines 251.

The switching operation is performed by the address signal that selectively switches some or all of the plurality of dump selection switches SWD1 to SWD4. The address signal is outputted from the dump decoder coupled to the plurality of dump selection switches SWD1 to SWD4.

In the transferring step, the binary information dumped to the plurality of second dump lines 251 is simultaneously transferred to at least one of the plurality of second memory cells 211.

The data may be dumped from the second memory chip 200 to the first memory chip by an operation similar to the operation described above.

As described above, according to the present invention, the data stored in the plurality of first type memory cells 111 of the first memory chip 100 may be directly dumped to the plurality of second type memory cells 211 of the second memory chip 200. That is, the data stored in the first memory chip 100 may be directly transferred to the second memory chip 200 without the lines and the peripheral circuits coupled to the outside.

Thus, the data transfer speed between the first memory chip 100 and the second memory chip 200 is greatly increased and the data capacity of the stack memory device 50 is greatly increased.

In FIGS. 1 to 3, since a width of lines of a conductive material that constitutes the plurality of first dump lines 151 of the first memory chip 100 and the plurality of second dump lines 251 of the second memory chip 200 may be shallow in order to smoothly couple the plurality of first dump lines 151 of the first memory chip 100 and the plurality of second dump lines 251 of the second memory chip 200, a pad region where a conductive material of a coupling portion is wider than the lines of the conductive material of the dump lines of the first and second memory cell arrays 110 and 120 is formed.

As the plurality of first type memory cells 111 of the first memory chip 100 has a same pitch as the plurality of second type memory cells 211 of the second memory chip 200, the plurality of first dump lines 151 of the first memory chip 100 has a same pitch as the plurality of second dump lines 251 of the second memory chip 200.

When the data is dumped from the plurality of first type memory cells 111 of the first memory chip IOU to the plurality of second type memory cells 211 of the second memory chip 200, a parasitic element to be overcome is a parasitic resistance and a parasitic capacitance of the plurality of first dump lines 151 and the plurality of second dump lines 251. Since the data is transferred to a memory cell of a different memory chip through the plurality of first and second dump lines 151 and 251, the stacked memory device 50 having a stacked multi-layer substrate minimizes a parasitic element of the transfer path of the data and is appropriately used in a cache system which operates rapidly in response to an instruction of a central processing unit (CPU).

The plurality of first and second pads 141 and 241 that couple the plurality of first and second dump lines 151 and 251 to each other do not need to be disposed on a center of the first memory cell array 110 and the second memory cell array 210, and may be disposed on a near region of a sense amplifier (not shown) or a circuit for selecting a column. Also, it may be preferable that a region where the plurality of first and second dump lines 151 and 251 are bonded to each other is disposed on a core circuit region.

In all embodiments of the present invention, at least three memory chips may be stacked. That is, first to third memory chips are sequentially stacked, and the plurality of first and second pads 141 and 241 of the first memory chip 100 are electrically coupled to each other through pads of the third memory chip. A gate and a diffusion region of an active element such as a transistor are separately shown in the third memory chip. Like this, the number of stacked memory chips is not restricted theoretically, and the number of semiconductor element to be integrated in a small area increases as the plurality of memory chips are stacked.

In any embodiment of the present invention, the descriptions of the sense amplifier, a circuit for a column selection and a circuit for a row selection, which are disposed near to the plurality of first type and second type memory cells 111 and 2111 will be omitted for the convenience of the descriptions.

In any embodiment of the present invention, when the data is dumped from the plurality of first type memory cells 111 of the first memory chip 100 to the plurality second type memory cell 211 of the second memory chip 200 or from the plurality second type memory cell 211 of the second memory chip 200 to the plurality of first type memory cells 111 of the first memory chip 100, since there are no parasitic capacitance of a local data line, which expands along a word line direction of the first and second memory cell arrays 110 and 210, and no parasitic capacitance of a global data line, which couples array matrix, it does not need to overcome the parasitic capacitance of the local data line and the parasitic capacitance of the global data line.

Thus, a rapid data dump may be performed with little power consumption.

Although various embodiments have been described for illustrative purposes, it will be apparent to those skilled in the art that various changes and modifications may be made without departing from the spirit and scope of the invention as defined in the following claims.

What is claimed is:

1. A stack memory device, comprising:
a first memory chip including at least one cell array having a plurality of first type memory cells, wherein the plurality of first type memory cells are repeatedly arrayed along a row direction and a column direction and a dump line is coupled to each of the plurality of first type memory cells; and
a second memory chip including at least one cell array having a plurality of second type memory cells, wherein the plurality of second type memory cells are repeatedly arrayed along the row direction and the column direction and a dump line is coupled to each of the plurality of second type memory cells,
wherein a first pad is coupled to the dump line coupled to the plurality of first type memory cells, a second pad is coupled to the dump line coupled to the plurality of second type memory cells, and the first pad corresponds to the second pad by one to one.

2. The stack memory device of claim 1, wherein the first memory chip further includes a first dump selection switch.

3. The stack memory device of claim 1, wherein at least one of the first memory chip and the second memory chip further includes a dump selection switch for dumping data.

4. The stack memory device of claim 1, wherein a pitch of a row direction of the plurality of first type memory cells is same as a pitch of the row direction of the plurality of second type memory cells, or a pitch of a column direction of the plurality of first type memory cells is same as a pitch of the column direction of the plurality of second type memory cells.

5. The stack memory device of claim 1, wherein the first pad and the second pad is bonded using a through-silicon-via (TSV) or a direct bonding interconnect (DBI).

6. A method for operating a stack memory device, comprising steps of:
driving a plurality of first type memory cells, which are repeatedly arrayed along a row direction and a column direction and included in a first memory chip in the row direction;
loading binary information, which are stored in the plurality of first type memory cells by the driving of the first type memory cells, to a dump line coupled to each of the plurality of first type memory cells; and
transferring loaded binary information to a plurality of second type memory cells, which are repeatedly arrayed along the row direction and the column direction and included in a second memory chip.

7. The method for operating the stack memory device of claim 6, wherein the step of transferring is performed a switching operation of at least one switch among dump selection switches included in the first memory chip or dump selection switches included in the second memory chip.

8. The method for operating the stack memory device of claim 7, wherein the switching operation is performed by an address which selectively switch some or all of the dump selection switches coupled to a memory cell array including the plurality of first type memory cells or a memory cell array including the plurality of second type memory cells.

9. The method for operating the stack memory device of claim 6, wherein the step of transferring is performed by a first pad coupled to the plurality of first type memory cells and a second pad coupled to the plurality of second type memory cells, and the first pad and the second pad are bonded to each other using a through-silicon-via (TSV) or a direct bonding interconnect (DBI).

10. A stack memory device, comprising:
a first memory chip including a plurality of first type memory cells, a plurality of first pads and a plurality of first dump lines, wherein the plurality of first type memory cells are repeatedly arrayed along a row direction and a column direction, and the plurality of first dump lines couple the plurality of first type memory cells to the plurality of first pads by one to one; and
a second memory chip including a plurality of second type memory cells, a plurality of second dump lines, a plurality of second pads and a plurality of dump selection switches, wherein the plurality of second type memory cells are arrayed along the row direction and the column direction, each of the plurality of second dump lines are coupled to each of the plurality of second type memory cells, the plurality of second pads are coupled to the plurality of second dump lines, and each of the plurality of dump selection switches is coupled to a specific location of each of the plurality of second dump lines,
wherein the plurality of first pads are coupled to the plurality of second pads by one to one, and the plurality of second pads are coupled to the plurality of second dump lines by one to multiple.

11. The stack memory device of claim 10, wherein a pitch of a row direction of the plurality of first type memory cells is same as a pitch of the row direction of the plurality of second type memory cells, and a pitch of a column direction of the plurality of first type memory cells is same as a pitch of the column direction of the plurality of second type memory cells.

12. The stack memory device of claim 10, wherein the second memory chip further includes a dump decoder for indicating an address of the plurality of dump selection switches.

13. The stack memory device of claim 10, wherein the plurality of first pads and the plurality of second pads are bonded to each other using one of a through-silicon-via (TSV) and a direct bonding interconnect (DBI).

14. A method for operating a stack memory device, comprising steps of:
driving a plurality of first type memory cells, which are arrayed along a row direction and a column direction, in the row direction;
loading binary information, which are stored in the plurality of first type memory cells by the driving of the plurality of first type memory cells, to a plurality of first dump lines;
dumping the binary information, which are loaded on the plurality of first dump lines, to each of a plurality of second dump lines coupled to the plurality of first dump lines; and
transferring the binary information, which are dumped to the plurality of second dump lines, to a plurality of second type memory cells coupled to each of the plurality of second dump lines.

15. The method for operating the stack memory device of claim 14, wherein the step of transferring is performed by at least one switching operation among a plurality of dump selection switches coupled to each of the plurality of second dump lines.

16. The method for operating the stack memory device of claim 15, wherein the switching operation is performed by an address signal that selectively switches some or all of the plurality of dump selection switches.

17. The method for operating the stack memory device of claim 14, wherein in the step of transferring, the binary information, which are dumped to the plurality of second dump lines, are simultaneously transferred to at least one of the plurality of second type memory cells.
